(19) United States
(12) Patent Application Publication
(10) Pub. No.: US 2012/0319207 A1
(43) Pub. Date: Dec. 20, 2012

(54) SEMICONDUCTOR DEVICE WITH THRESHOLD VOLTAGE CONTROL AND METHOD OF FABRICATING THE SAME

(75) Inventor: Ryosuke Iijima, Tokyo (JP)

(73) Assignee: TOSHIBA AMERICA ELECTRONIC COMPONENTS, INC., Irvine, CA (US)

(21) Appl. No.: 13/162,825

(22) Filed: Jun. 17, 2011

(51) Int. Cl. H01L 27/092; H01L 21/336; H01L 29/78

(52) U.S. Cl. 257/369; 257/405; 438/197; 257/E27.062; 257/E29.255; 257/E21.409

(57) ABSTRACT

Semiconductor devices and methods of making semiconductor devices are provided. According to one embodiment, the field effect transistor can contain a semiconductor substrate containing shallow trench isolations; a p-FET and an n-FET; a silicon germanium layer in a recess in the upper surface of the p-FET; a pair of gate dielectrics including a hafnium compound and a rare earth compound disposed on the silicon germanium layer and the upper surface of the n-FET; and a pair of gate electrodes both including the same material disposed on the pair of gate dielectrics.

### FIELD

Embodiments described herein relate generally to field effect transistors having a channel silicon germanium layer and methods for fabricating field effect transistors having a channel silicon germanium layer.

### BACKGROUND

Silicon large-scale integrated circuits, among other device technologies, are increasing in use in order to provide support for the advanced information society of the future. To produce an integrated circuit with highly sophisticated functions, semiconductor devices that yield high performance, such as MOSFETs or CMOSFETs (Complementary MOSFETs), can be utilized to constitute an integrated circuit.

In the design of a MOSFET, a CMOSFET, and/or similar devices, formation of gate electrodes having respective optimum threshold voltage(s) according to factors such as device structure, conductivity types, operation voltage etc., can complicate the production process of such devices. This added complication can, in turn, increase the production costs for such devices, reduce the reliability of the device and/or introduce a loss of efficiency or other such effects. Accordingly, it would be desirable to implement techniques for controlling a threshold voltage of each electrode corresponding to a MOSFET, CMOSFET, or the like through simple, easily implementable procedures.

### BRIEF DESCRIPTION OF THE DRAWINGS

FIG. 1 is a cross-sectional illustration of portions of an example MOSFET in accordance with an embodiment of the subject innovation.

FIG. 2 illustrates voltage shifts of respective semiconductor devices in accordance with various embodiments of the subject innovation.

FIG. 3 illustrates modulation of the valence bands of respective semiconductor devices in accordance with various embodiments of the subject innovation.

FIG. 4 is a cross-sectional illustration of portions of an example semiconductor device in accordance with an embodiment of the subject innovation.

FIGS. 5 to 12 illustrate an example methodology for fabricating a semiconductor device in accordance with an embodiment of the subject innovation.

FIG. 13 is a flow diagram of an exemplary methodology of forming a semiconductor device in accordance with an aspect of the subject innovation.

### DETAILED DESCRIPTION

The subject innovation described herein provides field effect transistors and manufacturing field effect transistors. In particular, the subject innovation provides field effect transistors having a channel silicon germanium layer, and a gate dielectric including a Hafnium compound and a Rare Earth compound. The field effect transistor contains the silicon germanium layer between a semiconductor substrate, and the gate dielectric.

The silicon germanium layer can have a bottom surface and a top surface having a (100) plane and side surfaces having two or more planes. The silicon germanium can have a substantially uniform height over a channel region of the field effect transistor. In one embodiment, the silicon germanium layer has no side surface at a portion of the semiconductor substrate that is covered with the gate feature in a direction of channel length. In another embodiment, the silicon germanium has all the side surfaces at portions of the semiconductor substrate that are not covered with the gate feature. The field effect transistor can improve one or more of on current (Ion) characteristics, linear drain current (Idlin) characteristics, and threshold voltage (Vt) characteristics because of the channel silicon germanium layer.

The field effect transistor can contain a semiconductor substrate containing source/drain regions and shallow trench isolations in the semiconductor substrate. The field effect transistor can further contain a silicon germanium layer in a trench at an upper surface of the semiconductor substrate between the shallow trench isolations; a gate feature on the silicon germanium layer containing a dielectric, a gate electrode, and side spacers; and metal silicides on the upper portions of silicon germanium layer and semiconductor substrate that are not covered by the gate feature.

In another embodiment, the field effect transistor contains a semiconductor substrate containing source/drain regions between shallow trench isolations and a silicon germanium layer in a trench at a substantially whole upper surface of the semiconductor substrate between the shallow trench isolations; a gate feature on the silicon germanium layer containing a gate dielectric including a Hafnium compound and a Rare Earth compound, and a gate electrode. The field effect transistor can further contain side spacers and metal suicides on the upper portions of silicon germanium layer and semiconductor substrate that are not covered by the gate feature. The silicon germanium layer has a bottom surface and a top surface having a (100) plane and side surfaces having two or more planes. The silicon germanium layer has no side surface under the gate feature in a direction of channel length.

The following description and the annexed drawings set forth certain illustrative aspects of the specification. These aspects are indicative, however, of but a few of the various ways in which the principles of the specification may be employed. Other advantages and novel features of the specification will become apparent from the following detailed description of the disclosed information when considered in conjunction with the drawings.

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices may be shown in block diagram form in order to facilitate describing the claimed subject matter.

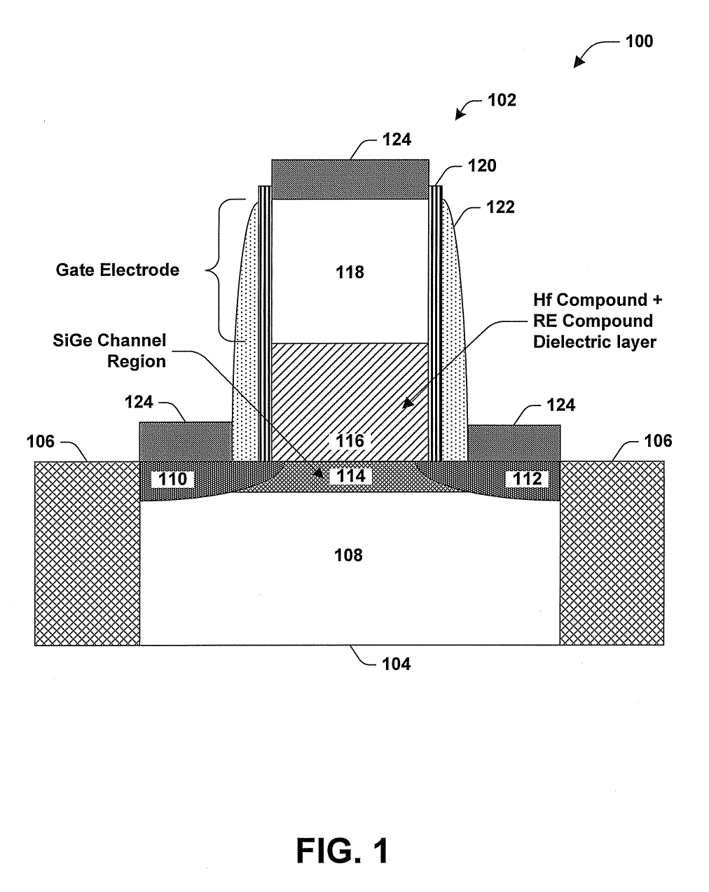

Referring first to FIG. 1, a cross-sectional illustration of an example semiconductor device 100 is provided in accordance with an embodiment. As shown in FIG. 1, the semiconductor device 100 can include a metal-oxide-semiconductor (MOS) transistor or MOSFET 102. The semiconductor device 100 can also include a silicon substrate 104, and isolation features 106. In a non-limiting example, MOSFET 102 can be a p-type transistor (also referred to as a pMOS or p-FET). Isolation features 106 can be STIs (shallow trench isolation). Further, substrate 104 can be a silicon substrate.

According to an embodiment, MOSFET 102 can include an active region 108 formed on substrate 104. In addition, MOSFET 102 includes a source region 110 and a drain region 112 formed in the active region 108, with source region 110 and drain region 112 being separated from one another. A channel region 114, formed in the active region 108, can be formed between the source region 110 and drain region 112. The channel region 114 can be constructed to incorporate germanium (Ge), for example, using a material such as silicon germanium (SiGe).

The MOSFET 102 can include a dielectric layer 116. The dielectric layer 116 having a material having a high dielectric constant, k (or high-k dielectric). For instance, the high-k dielectric can comprise a variety of Hafnium (Hf) Compounds in combination with a Rare Earth (RE) Compound. In a non-limiting example, the high-k dielectric can comprise Hf oxide and Lanthanum (HfO2+La). In further non-limiting examples, the Hf Compounds can include Zirconium (Zr) oxide, HfZr oxide, Hf silicate, Zr silicate, or HfZr silicate, and the RE Compound can include a RE metal (REM) and/or RE oxide (REO), such as Yttrium (Y), Dysprosium (Dy), Strontium (Sr), Barium (Ba), Ytterbium (Yb), Lutetium (Lu), Magnesium (Mg), Beryllium (Be), Scandium (Sc), Cerium (Ce), Praseodymium (Pr), Neodymium (Nd), Europium (Eu), Gadolinium (Gd), Terbium (Tb), or Erbium (Er). It should be appreciated, however, that the preceding list is provided merely by way of example and that other compositions could also be utilized.

MOSFET 102 can further include a gate electrode 118 situated on the dielectric layer 116. As illustrated, the gate electrode 118 can include a single conductive layer gate. However, it is to be appreciated that the gate electrode 118 can additionally comprise a multiple conductive layer gate. In a further non-limiting example, the gate electrode 118 can be formed using a metal or metallic alloy. Specific non-limiting examples of compositions that can be utilized for the gate electrode 118 include metals such as Ti, Hf, Ta, W, Al, Ru, Pt, Re, Cu, Ni, Pd, Ir, and/or Mo; nitrides and carbides such as TiN, TaN, TiC, TaC, WN, WC, and/or HfN; conductive oxides such as RuOx and/or ReOx; metal-metal-alloys such as Ti—Al, Hf—Al, Ta—Al, and/or TaAlN; multi-stacked structures of the preceding compositions, such as TiN/W, TiN/Ti—Al, Ta/TiN/Ti—Al, or the like. It should be appreciated, however, that the preceding list is provided by way of example and that other compositions could be utilized for the gate electrode.

In a further embodiment, MOSFET 102 can include a first spacer 120, a second spacer 122, and a silicide layer 124. The silicide layer 124 can be stacked upon the gate electrode 118 and/or upon the source region 110 and drain region 112. The silicide layer 124 can be constructed with a Si and metal-silicide, such as NiSiₓ, PtSiₓ, PdSiₓ, CoSiₓ, TiSiₓ, WSiₓ, etc. It should be appreciated, however, that the preceding list is provided by way of example and that other compositions could be utilized for silicide layer 124.

The MOSFET 102 can have any suitable channel width. The channel width is generally a length of the active region 108 in a longitudinal direction of the active region 108. The channel width is typically about 100 nm or more and about 2,000 nm or less. The MOSFET can have any suitable channel length. The channel length is generally defined between the corresponding source 110 and drain 112 regions. The channel length is generally about 10 nm or more and about 100 nm or less. The MOSFET 102 can have any suitable channel height. The channel height is generally defined between the bottom surface of the channel and the top surface of the channel. In one embodiment, the channel height is about 2 nm or more and about 25 nm or less. In an additional embodiment, the channel height is about 5 nm or more and about 15 nm or less. Moreover, the MOSFET 102 can have any suitable dielectric height. In one embodiment, the dielectric height is about 1 nm or more and about 10 nm or less. In an additional embodiment, the dielectric height is about 2 nm or more and about 5 nm or less.

Although not shown in FIG. 1 for brevity, the MOSFET 102 can contain any feature that can be normally employed in field effect transistor structures. For example, gate contact plugs, source-drain contacts, insulating layer between gate features, and the like can be further contained in the MOSFET 102.

The channel 114 has a bottom surface and side surfaces. The bottom surface has a (100) plane (e.g., plane direction or plane orientation) or a plane equivalent thereto (e.g., (100), (010), or (001) plane) (referred to collectively hereinafter as “(100) plane”). The side surface of the trench can contain a (111) plane or a plane equivalent thereto (referred to collectively hereinafter as “(111) plane”) and other planes. The side surface does not substantially contain only a (111) plane. In other words, the side surface of the trench has two or more different planes.

The silicon germanium layer has a bottom surface and a top surface. The bottom and top surfaces have a (100) plane. The silicon germanium layer further has side surfaces. The side surface of the silicon germanium layer can contain a (111) plane and other planes. The side surface of the silicon germanium does not substantially contain only a (111) plane. In other words, the side surface of the silicon germanium has two or more different planes.

The silicon germanium layer has any suitable amount of germanium as long as the amount of germanium can increase hole mobility in the channel region. In one embodiment, the silicon germanium layer contains about 0 wt. % or more and about 80 wt. % or less of silicon and about 20 wt. % or more and about 100 wt. % of germanium. In another embodiment, the silicon germanium layer contains about 30 wt. % or more and about 75 wt. % or less of silicon and about 25 wt. % or more and about 70 wt. % of germanium. In yet another embodiment, the silicon germanium layer contains about 60 wt. % or more and about 70 wt. % or less of silicon and about 30 wt. % or more and about 40 wt. % of germanium.

With respect to the construction of MOSFT 102, as well as various other semiconductor devices as illustrated and described herein, it can be appreciated that the formation of gate electrodes having the respective optimum threshold voltages according to device structure, conductivity types, operation voltage, etc., can be complicated and introduce negative effects. Accordingly, it can be appreciated that mechanisms for controlling a threshold voltage of a semiconductor device through stable and reliable procedures are desirable. Thus, according to an embodiment, an additional element, which is not a main component of substrates in a semiconductor device, can be added in the channel layer 114. In one example, a shift in the threshold voltage can be achieved based, at least in part, on an amount of the additional element introduced to the channel layer 114. By constructing a semiconductor device in this manner, it can be appreciated that a work function can be easily modulated via less variables and more reliable procedures as compared to conventional methods, resulting in improvement of device performance.

With respect to the above and the embodiments that follow, it can be appreciated that while FIG. 1 and the respective other illustrations provided herein show examples of semiconductor devices for which the embodiments can be implemented, the embodiments described herein may also be applicable for novel channel devices (e.g., SiC, SiGeC, III-V materials, etc.), novel device structures (e.g., Si on insulator (SOI), 3-dimensional transistors (e.g., finFET, verticalFET, nanowire, nanotube, . . . ), etc.), and/or any other suitable device type(s).

According to an embodiment, enhanced threshold voltage control for semiconductor device 100 can be achieved by introducing an additional element to channel layer 114 and introducing an additional element to dielectric layer 116. By way of example, as shown in FIG. 1, Ge can be incorporated into channel layer 114, thereby effecting a positive threshold voltage shift for the semiconductor device 100, wherein the semiconductor device is a p-type or p-FET, and the dielectric layer 116 includes a RE compound. This technique is in contrast to conventional semiconductor fabrication techniques, where RE compounds, such as La, are used exclusively in the dielectric layer of n-FET devices, because RE compounds, typically, effect a negative threshold voltage shift for p-FET devices.

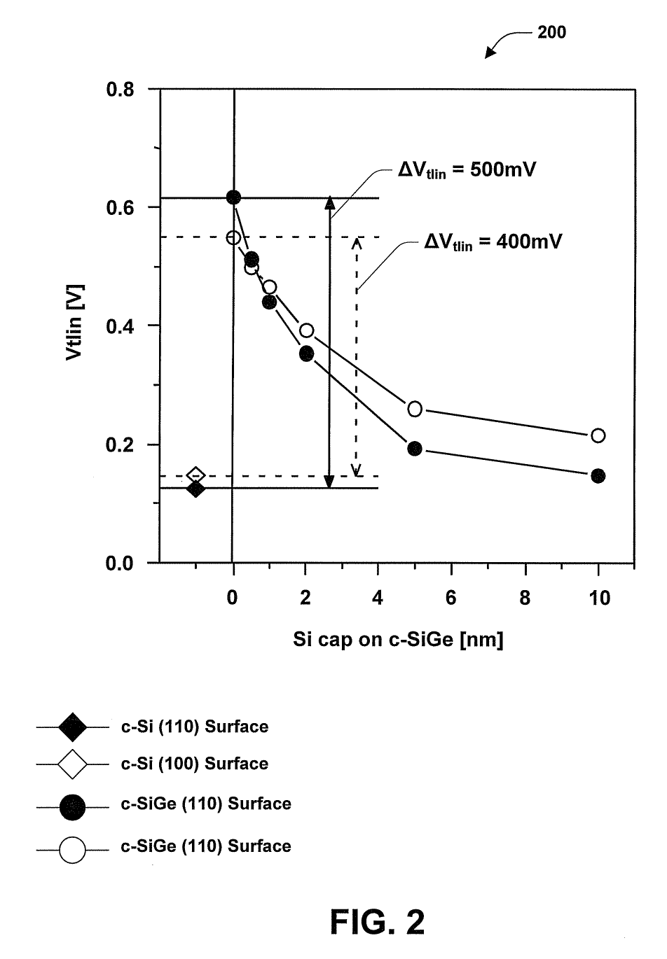

For example, as shown in FIG. 2, graph 200 depicts a shift or delta (in millivolts (mV)) of the linear threshold voltage (Vₜₗᵢₙ) relative to a channel layer Silicon (Si) cap on channel silicon germanium (c-SiGe) (in nanometers (nm)). As the Si cap increases, the linear threshold voltage decreases. Graph 200 illustrates that the Vₜₗᵢₙ is shifted no more than about 500 mV to the positive direction by the generated negative static charge that results from using c-SiGe in place of c-Si in a channel layer of a p-FET having a dielectric layer constructed using a Hf Compound in combination with a RE Compound for a (110) surface, and no more than about 400 mV to the positive direction for a (100) surface.

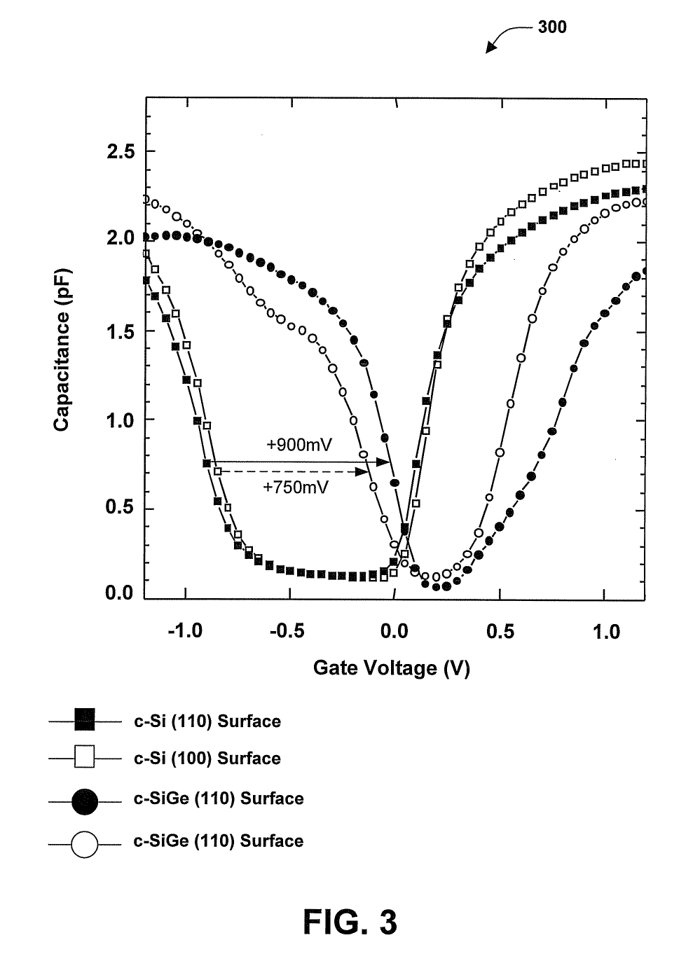

As an additional example, as shown in FIG. 3, graph 300 depicts a Gate Voltage (V) (upon which a threshold voltage (Vt) depends) relative to a capacitance (pF) for channel silicon (c-Si) and channel Silicon Germanium (c-SiGe). Graph 300 illustrates the effect of the modulation of the valence band, and that employing c-SiGe in place of c-Si in a channel layer of a p-FET having a dielectric layer constructed using a Hf Compound in combination with a RE Compound will result in a Vt shift of no more than about 900 mV for a (110) surface and no more than about 750 mV for a (100) surface.

Referring next to FIG. 4, a cross-sectional illustration of an example semiconductor device 400 is provided in accordance with an embodiment. As shown in FIG. 4, semiconductor device 400 can include a first transistor or metal-oxide-semiconductor (MOS) transistor (also referred to as MOSFET) 401 and a second transistor or MOSFET 403. Semiconductor device 400 can also include a silicon substrate 402 that includes a first active region 404 and a second active region 406 separated by isolation features 408. The MOSFET 401 can be constructed on the first active region 404 of substrate 402, and the MOSFET 403 can be constructed on the second active region 406. The isolation features 408 can be shallow trench isolation (STIs). Further, substrate 402 can be a silicon substrate.

According to an embodiment, the MOSFET 401 and the MOSFET 403 can be different conductivity types, for example, the MOSFET 401 can be a p-type transistor (also referred to as a pMOS or p-FET), and the MOSFET 403 can be an n-type transistor (also referred to as an nMOS or n-FET). In this embodiment, the semiconductor device 400 is a complementary MOSFET device (also referred to as a CMOS device), wherein the p-FET 401 and the n-FET 403 are complementary and constructed on the same substrate 402. The MOSFET 401 is substantially same as the MOSFET 102 as in FIG. 1.

The p-FET 401 can further include a source region 410 and a drain region 411 formed in the active region 404, with the source region 410 and the drain region 411 being separated from one another. A channel region 412, formed in the active region 404, can separate source region 410 and drain region 411. In a specific, non-limiting example, the channel region 412 can contain a channel material such as channel silicon germanium (c-SiGe).

In addition, the p-FET 401 can further include a dielectric layer 414. The dielectric layer 414 having a high-k dielectric. For instance, the high-k dielectric can comprise a variety of Hafnium (Hf) Compounds in combination with a Rare Earth (RE) Compound. In a non-limiting example, the high-k dielectric can comprise Hf oxide and Lanthanum (HfO2+La). In further non-limiting examples, the Hf Compounds can include Zr oxide, HfZr oxide, Hf silicate, Zr silicate, or HfZr silicate, and the RE Compound can include a RE metal (REM) and/or RE oxide (REO), such as Y, Dy, Sr, Ba, Yb, Lu, Mg, Be, Sc, Ce, Pr, Nd, Eu, Gd, Tb, or Er. It should be appreciated, however, that the preceding list is provided merely by way of example and that other compositions could also be utilized.

The p-FET 401 can further include a gate electrode 416 situated on the dielectric layer 414. In an embodiment, the gate electrode 416 can include a single conductive layer gate. However, it is to be appreciated that the gate electrode 416 can comprise a multiple conductive layer gate. In a further non-limiting example, the gate electrode 414 can be formed using a metal or metallic alloy. Specific examples of compositions that can be utilized for the gate electrode 416 include metals such as Ti, Hf, Ta, W, Al, Ru, Pt, Re, Cu, Ni, Pd, Ir, and/or Mo; nitrides and carbides such as TiN, TaN, TiC, TaC, WN, WC, and/or HfN; conductive oxides such as RuOx and/or ReOx; metal-metal-alloys such as Ti—Al, Hf—Al, Ta—Al, and/or TaAlN; multi-stacked structures of the preceding compositions, such as TiN/W, TiN/Ti—Al, Ta/TiN/Ti—Al, or the like. It should be appreciated, however, that the preceding list is provided by way of example and that other compositions could be utilized for the gate electrode.

In a further embodiment, the p-FET 401 can include a first spacer 418, a second spacer 420, and a silicide layer 422. The suicide layer 422 can be stacked upon the gate electrode 416 and/or upon the source region 410 and drain region 412. The silicide layer 422 can be constructed with a Si and metal-silicide, such as NiSiₓ, PtSiₓ, PdSiₓ, CoSiₓ, TiSiₓ, WSiₓ, etc. It should be appreciated, however, that the preceding list is provided by way of example and that other compositions could be utilized for silicide layer 422.

Similar to the p-FET 401, the n-FET 403 can include a source region 426 and a drain region 428 formed in the active region 406, with the source region 406 and the drain region 428 being separated from one another. A channel region (not shown), formed in the active region, can separate source region 408 and drain region 410.

In addition, the n-FET 403 can further include a dielectric layer 432. The dielectric layer 432 having a high-k dielectric substantially identically or similar to the high-k dielectric in the dielectric layer 414. For example, the dielectric layer 414 and the dielectric layer 432 can be constructed using the same Hf Compounds in combination with a RE Compound, such as HfO2+La. The n-FET 403 can further include a gate electrode 434 situated on the dielectric layer 432. In an embodiment, the gate electrode 434 can include a single conductive layer gate. However, it is to be appreciated that the gate electrode 434 can comprise a multiple conductive layer gate. In a further non-limiting example, the gate electrode 434 can be formed using the same metal or metallic alloy used for the gate electrode 416.

In a further embodiment, the n-FET 403 can include a first spacer 438, a second spacer 440, and a silicide layer 442. Similar to the silicide layer 442, the silicide layer 442 can be stacked upon the gate electrode 434 and/or upon the source region 426 and drain region 428, and can be constructed with a Si and metal-silicide.

As illustrated in FIG. 4, the germanium (Ge) concentration compared to Silicon (Si) in the uppermost surface of the substrate 402 is higher in the P-FET 401 than in the n-FET 403. The SiGe in the channel 412 enables the use of the RE compound in combination with the Hf compound in the dielectric layer 414. RE compounds, such as La, for instance, are typically used only on in an N-FET, because La generally shifts the Vt of a p-FET in the negative direction making it undesirable for use in a high-K dielectric for a p-FET. However, the Vt of the p-FET 404 can be shifted to the positive (e.g., plus) direction by substituting Si for SiGe in the channel 412 (see FIGS. 2-3).

Employing a high-k dielectric consisting of a combination of a Hf Compound and a RE compound disposed, as the dielectric layer 414, on channel SiGe shifts the Vt of the p-FET 404 to the positive direction, which enables the dielectric layer 414 and the dielectric layer 432 to employ a single high-k dielectric, for example, HfO2+La. Moreover, the gate electrode 416 and the gate electrode 434 can employ the same gate electrode materials (discussed supra). Therefore, the foregoing can provide for a simplified structure over CMOS devices that typical employ different high-k dielectric materials for the p-FET and the n-FET, and different metal gate materials for the p-FET and the n-FET.

With respect to the construction of semiconductor device 400, as well as various other semiconductor devices as illustrated and described herein, it can be appreciated that the formation of gate electrodes having the respective optimum threshold voltages according to device structure, conductivity types, operation voltage, etc., can be complicated and introduce negative effects. Accordingly, it can be appreciated that mechanisms for controlling a threshold voltage of a semiconductor device through stable and reliable procedures are desirable.

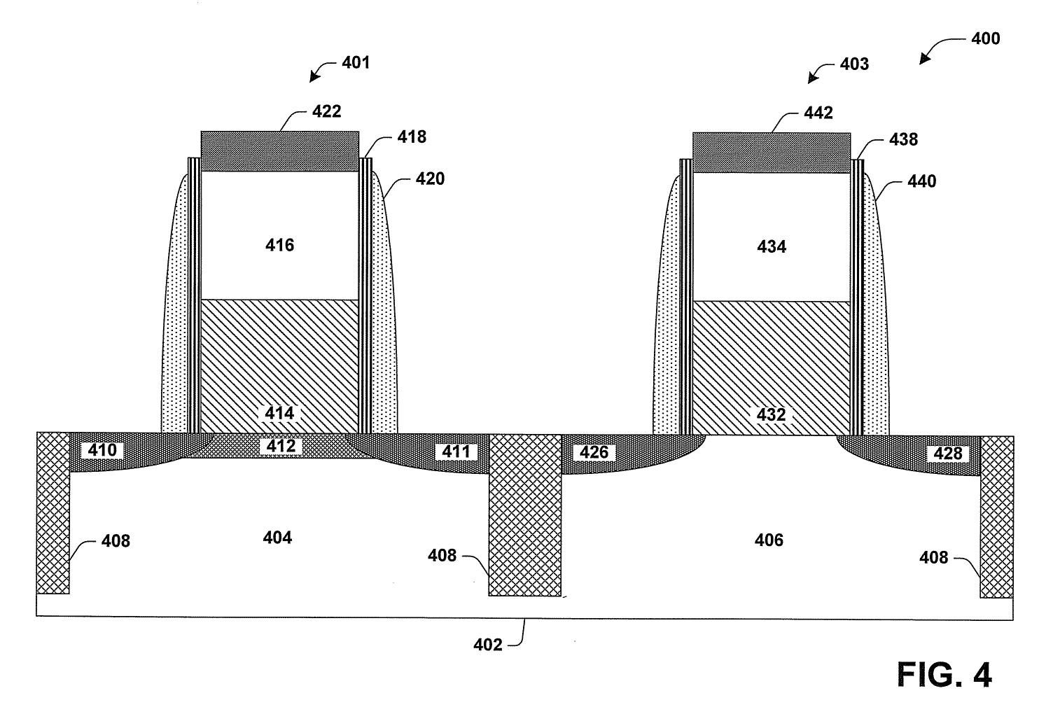

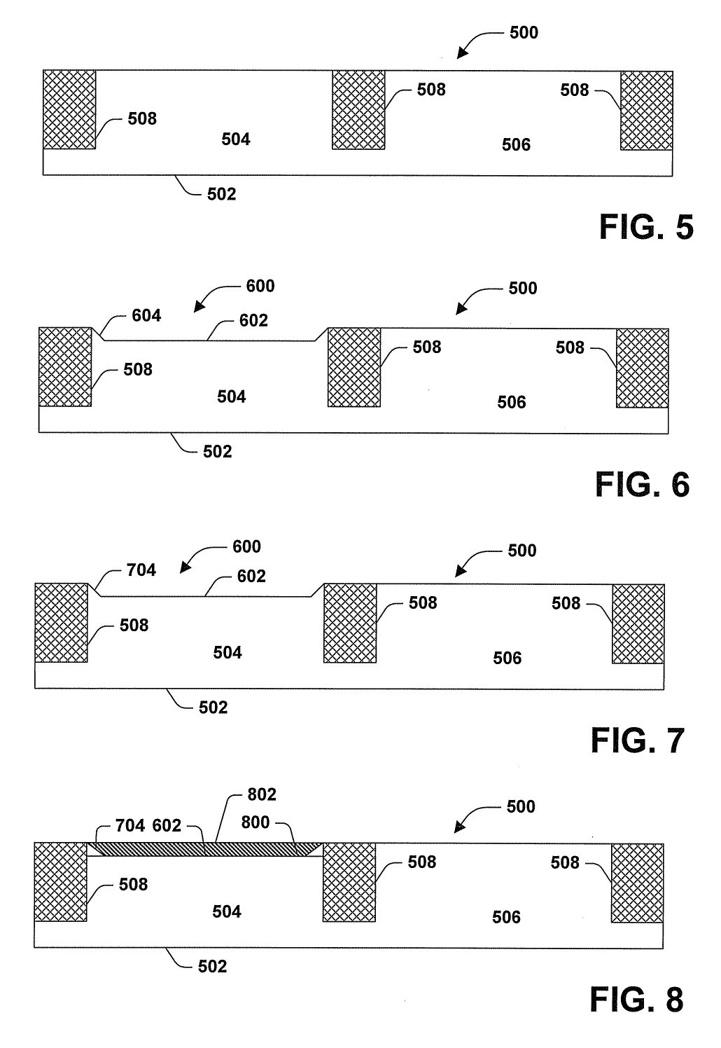

Referring to FIG. 5 to FIG. 12, one of many possible exemplary embodiments of forming a field effect transistor is specifically illustrated. FIG. 5 is a cross-sectional isometric illustration of an intermediate state of an exemplary field effect transistor 500.

The field effect transistor 500 can contain a substrate (e.g., silicon substrate) 502, a first active region 504, and a second active region 506 separated by STIs 508 in the semiconductor substrate. The STI can be formed by chemical vapor deposition (CVD), lithography, and etching techniques. A patterned hard mask is formed on the semiconductor substrate. Portions of the semiconductor substrate that are not covered by the patterned hard mask are removed by, for example, etching to make openings in the semiconductor substrate. The STI can be formed by filling the openings with the STI material.

Although not shown in FIG. 5, a well and a channel can be formed in the active regions 504 and 506 between the semiconductor substrate between the STIs. For example, when the field effect transistor is a p-type transistor, a well is formed by implantation of one or more N dopants (e.g., phosphorus) and a channel is formed by implantation of one or more N dopants (e.g., arsenic). In an embodiment, a p-type transistor (also referred to as a pMOS or p-FET) can be formed in the active region 504, and an n-type transistor (also referred to as an nMOS or n-FET) can be formed in the active region 506.

FIG. 6 illustrates forming a recess 600 at the top portion of the semiconductor substrate 502 at the substantially whole upper most portion of the active region 504 by removing portions of semiconductor substrate 502 between the STIs 508. The recess can be formed by using an anisotropic chemical wet etching. When an oxide is formed on the semiconductor substrate before the anisotropic chemical wet etching, the oxide can be removed by using a diluted hydrofluoric acid (HF). The semiconductor substrate can be briefly dipped into the diluted HF.

The recess can be formed by any suitable anisotropic chemical wet etching as long as the etching forms a recess having a bottom surface 602 having a (100) plane. The anisotropic chemical wet etching generally forms a bottom surface of a (100) plane and side surfaces (e.g., side facets) 604 having a (111) plane.

Examples of etchants of anisotropic chemical wet etching include base solutions such as tetraalkylammonium hydroxides (e.g., tetramethylammonium hydroxide (TMAH)) and ammonium hydroxide (NH4OH). By way of example, forming a recess using a TMAH solution is described below. Forming the recess using the TMAH solution is typically administered by immersing the semiconductor structure 500 into the TMAH solution or spraying/spreading the TMAH solution over the top of the semiconductor structure 500.

The TMAH solution may contain a sufficient amount of TMAH to facilitate removing portions of the semiconductor structure 500 without substantially damaging or etching other components. In one embodiment, the TMAH solution contains about 0.5% of TMAH by weight or more and about 40% of TMAH by weight or less. In another embodiment, the TMAH solution contains about 1% of TMAH by weight or more and about 25% of TMAH by weight or less. TMAH may be diluted in water, such as de-ionized water, to produce the TMAH solution having a desired concentration of TMAH.

The semiconductor substrate 502 is contacted with the TMAH solution at a suitable temperature to facilitate forming the recess. In one embodiment, the semiconductor substrate is contacted with the TMAH solution at a temperature of about 20 degrees Celsius or more and about 100 degrees Celsius or less. In another embodiment, the semiconductor substrate is contacted with the TMAH solution at a temperature of about 30 degrees Celsius or more and about 60 degrees Celsius or less. The semiconductor substrate is contacted with the TMAH solution for a suitable time to facilitate forming the recess. In one embodiment, the semiconductor substrate is contacted with the TMAH solution for about 5 seconds or more and about 20 minutes or less. In one embodiment, the semiconductor substrate is contacted with the TMAH solution for about 10 seconds or more and about 15 minutes or less. For example, the semiconductor substrate is contacted with a TMAH solution that contains about 2.5% of TMAH by weight, at a temperature of about 45 degrees Celsius, for about 2.5 minutes.

In another embodiment, the etchant is a NH4OH solution. NH4OH may be diluted in water, such as de-ionized water, to produce the TMAH solution having a desired concentration of NH4OH (e.g., NH4OH:H2O=1:3,000 (wt/wt)). The semiconductor substrate is contacted with a NH4OH solution at a temperature of about 45 degrees Celsius, for about 100 seconds.

The recess 600 can have any suitable depth. The recess can have a substantially uniform depth. The depth may vary and may not be critical to the subject innovation. The depth may depend on, for example, the desired implementations of the field effect transistor being fabricated. In one embodiment, the depth of the trench is about 5 nm or more and about 15 nm or less. In another embodiment, the depth is about 2 nm or more and about 25 nm or less. In still yet another embodiment, the depth is about 10 nm.

FIG. 7 illustrates heating the semiconductor substrate to change a plane direction of the side surfaces of the recess 600. When the side surface has a single plane direction, the heat treatment changes the single plane direction to two or more plane directions. When the side surface has a single (111) plane, the heat treatment changes the single (111) plane to two or more planes containing, for example, a (111) plane, a (112) plane, a (200) plane, a (101) plane, a (011) plane, and the like. Due to the heat treatment, the recess 600 can have two or more planes of the side surfaces 704. The (100) plane of the bottom surface can be remained unchanged. The semiconductor substrate can be recrystallized by the heat treatment.

The semiconductor substrate 502 can be heated under any suitable condition to facilitate forming two or more planes of side surfaces of the recess and/or recrystallization of the semiconductor substrate. In one embodiment, the semiconductor substrate is heated in hydrogen at a temperature of about 700 degrees Celsius or more and about 900 degrees Celsius or less for about 1 minute or more and about 10 minutes or less. In another embodiment, the semiconductor substrate is heated in hydrogen at a temperature of about 500 degrees Celsius or more and about 900 degrees Celsius or less for about 10 seconds or more and about 30 minutes or less.

FIG. 8 illustrates forming a silicon germanium layer 800 in the recess. The silicon germanium layer can be formed by epitaxial technique. The silicon germanium epitaxial growth can proceed under any suitable condition, for example, at elevated temperatures (e.g., 1,100 degrees Celsius) using a silicon source gas (e.g., SiH4, Si2H6, SiH8, SiF4, and the like), a germanium source gas (e.g., GeH4, GeF4, and the like), and optionally a carrier gas. The silicon germanium epitaxial growth can be terminated when the upper surface of the silicon germanium is substantially coplanar with the upper surfaces of the semiconductor substrate and/or STIs.

In one embodiment, the silicon germanium layer has a (100) plane of the bottom surface 602 when the trench has a (100) plane of the bottom surface. The silicon germanium layer can have a (100) plane of the top surface 802. In another embodiment, the silicon germanium layer has two or more different planes of side surfaces 704 when the trench has side surfaces having two or more different planes. In yet another embodiment, the silicon germanium layer has a substantially uniform height when the trench has a substantially uniform depth.

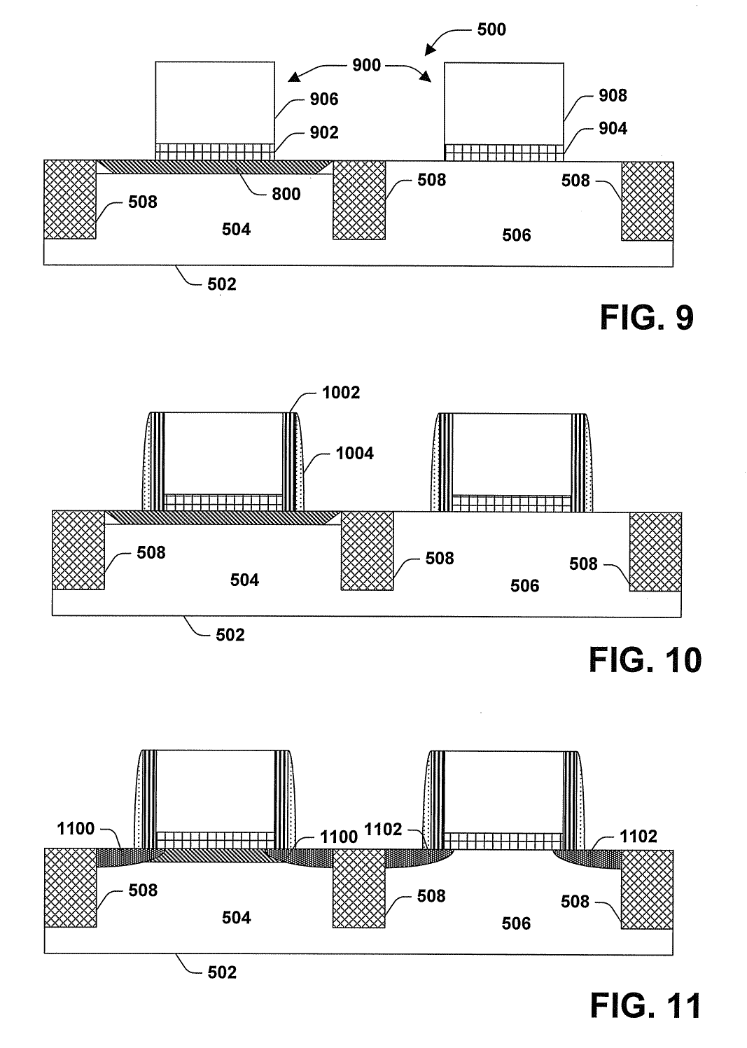

FIG. 9 illustrates forming gate features 900 containing a first gate dielectric layer 902 on the silicon germanium layer 800, and a second gate dielectric layer 904 on the upper most portion of the second active region 506. In addition, a first gate electrode 906 is disposed on the first gate dielectric layer 902, and a second gate electrode 908 is disposed on the second gate dielectric layer 904. The gate feature can be formed by forming a gate dielectric layer on the semiconductor device 500 and a gate electrode layer on the gate dielectric layer and patterning the gate dielectric layer and the gate electrode layer.

The gate dielectric layers 902 and 904 having a high-k dielectric. For instance, the high-k dielectric can comprise a variety of Hafnium (Hf) Compounds in combination with a Rare Earth (RE) Compound. In a non-limiting example, the high-k dielectric can comprise Hf oxide and Lanthanum (HfO2+La). In further non-limiting examples, the Hf Compounds can include Zr oxide, HfZr oxide, Hf silicate, Zr silicate, or HfZr silicate, and the RE Compound can include a RE metal (REM) and/or RE oxide (REO), such as Y, Dy, Sr, Ba, Yb, Lu, Mg, Be, Sc, Ce, Pr, Nd, Eu, Gd, Tb, or Er. It should be appreciated, however, that the preceding list is provided merely by way of example and that other compositions could also be utilized.

The gate dielectric layers 902 and 904 and the gate electrodes 906 and 908 can be formed by any suitable technique. For example, the gate dielectric layers 902 and 904 and the gate electrodes 906 and 908 can be formed by deposition (e.g., CVD, spin-on techniques, and the like), lithography, and etching techniques. In addition, the gate dielectric layers 902 and 904 can be formed by epitaxial growth techniques (e.g., silicon epitaxial growth) and oxidation techniques (e.g., thermal oxidation, plasma-assisted oxidation, and the like). Moreover, the RE Compound can be combined, added, or otherwise joined with the Hf compounds in the dielectric layer via implantation, doping, or any suitable technique.

The dielectric layers 902 and 904 and the gate electrodes 906 and 908 can have a substantially uniform height. The height may vary and may not be critical to the subject innovation. The height may depend on, for example, the desired implementations of the field effect transistor being fabricated. In one embodiment, the height of the dielectric layers 902 and 904 is about 1 nm or more and about 10 nm or less. In another embodiment, the height is about 2 nm or more and about 5 nm or less. In still yet another embodiment, the depth is about 2 nm.

FIG. 10 illustrates forming side spacers (e.g., side wall layers) 1002 adjacent the side surfaces of the gate dielectric layers 902 and 904 and the gate electrodes 906 and 908 and on the upper surface of the silicon germanium layer 800 or the upper most surface of the active region 506. The side spacer can contain any suitable insulating material such as oxides. Examples of oxides include silicon oxide, tetraethylorthosilicate (TEOS) oxide, high aspect ratio plasma (HARP) oxide, high temperature oxide (HTO), high density plasma (HDP) oxide, oxides (e.g., silicon oxides) formed by an atomic layer deposition (ALD) process, and the like. Other examples of side spacer materials include nitrides (e.g., silicon nitride, silicon oxynitride, and silicon rich silicon nitride), silicates, diamond-like carbon, carbide, and the like.

The side spacer can be formed by any suitable technique, for example, forming a layer containing the spacer material over the semiconductor substrate and then removing portions of the spacer material layer not near the side surface of the gate feature. The spacer material layer can be formed by deposition technique (e.g., CVD, spin-on techniques, and the like) at least over the side surface of the gate feature.

After forming the spacer material layer, portions of the spacer material layer can be removed, for example, etching. Any suitable etching can be used as long as the etching can leave a spacer adjacent the side surfaces of the gate insulating layer and gate electrode and on the silicon germanium layer. Wet etching and/or dry etching can be employed. Examples of etching include reactive ion etching (RIE), chemical plasma etching, or other suitable anisotropic etching utilizing a suitable chemistry.

Although not shown, source/drain extension regions and/or pocket regions can be formed before or after forming the side spacers 1002 and 1004. Any suitable implant compositions and concentrations can be employed for the source/drain extension regions. The source/drain extension region can be formed by any suitable technique. The source/drain extension region can be formed by implantation of one or more dopants. The dopants are implanted into the portions of semiconductor substrate that are not covered by the gate feature. The gate feature can serve as an implant screen. The source/drain extension region can be formed by implant with a relatively low energy level and/or a relatively low dose of dopants. In one embodiment, the source/drain extension region is formed at an energy level of about 0.1 KeV or more and about 1 KeV or less and a dose of about 1E14 atoms/cm2 or more and about 3E15 atoms/cm2 or less. In another embodiment, the source/drain extension region is formed at an energy level of about 1 KeV or more and about 5 KeV or less and a dose of about 5E13 atoms/cm2 or more and about 3E15 atoms/cm2 or less.

Similarly, any suitable implant compositions and concentrations can be employed for the pocket regions. The pocket implant can improve Vt characteristics of the field effect transistor. The pocket regions can have any suitable size, shape, implant composition, and concentration as long as the pocket region can improve contact punch-though leakage characteristics of the memory device. In one embodiment, the pocket regions have a tilt implant angle of about 0 degrees or more and about 40 degrees or less in the direction of the semiconductor substrate from an axis which is perpendicular to the surface of the semiconductor substrate. The pocket region can be formed by implantation of one or more dopants at any suitable implantation angle.

In one embodiment, the pocket region is formed at an energy level of about 25 KeV or more and about 60 KeV or less. In another embodiment, the pocket region is formed at an energy level of about 30 KeV or more and about 70 KeV or less. In one embodiment, the pocket region is formed at a dose of about 5E12 atoms/cm2 or more and about 8E13 atoms/cm2 or less. In another embodiment, the pocket region is formed at a dose of about 5E12 atoms/cm2 or more and about 1E14 atoms/cm2 or less.

FIG. 11 illustrates forming source/drain regions 1100 and 1102 in the semiconductor substrate 502 adjacent the gate features, and a second channel region (not shown) in the active region 506 of the semiconductor substrate between the source/drain regions 1100. Any suitable implant compositions and concentrations can be employed for the source/drain regions. For example, the source/drain regions 1100 include one or more n-type dopants (e.g., arsenic). Although not shown, the implanted dopants can be activated by annealing the semiconductor substrate.

The source/drain regions 1100 and 1102 can be formed by any suitable technique. The source/drain regions 1100 and 1102 can be formed by implantation of one or more dopants. The dopants are implanted into the portions of semiconductor substrate that are not covered by the gate feature and the side spacer. The gate feature and the side spacer can serve as an implant screen. The source/drain regions 1100 and 1102 can be formed by implant with a relatively high energy level and/or a relatively high dose of dopants. In one embodiment, the source/drain region is formed at an energy level of about 5 KeV or more and about 20 KeV or less and a dose of about 8E14 atoms/cm2 or more and about 1E16 atoms/cm2 or less. In another embodiment, the source/drain region is formed at an energy level of about 2 KeV or more and about 8 KeV or less and a dose of about 1E14 atoms/cm2 or more and about 1E16 atoms/cm2 or less. In still another embodiment, the source/drain region 900 can be formed by embedded epitaxial SiGe. The dopants can be formed by in-situ doped epitaxial.

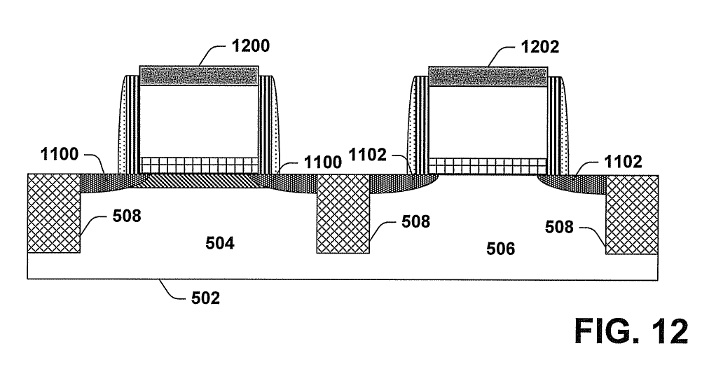

FIG. 12 illustrates forming metal silicides (not shown) on the portions of the silicon germanium layer 800 and semiconductor substrate 502 that are not covered by the gate feature (e.g., the gate feature and the side spacer). When the gate electrodes contain silicon, metal silicides 1200 and 1202 are formed on the gate electrodes. The metal silicides can be formed by a chemical reaction of a metal layer formed over the field effect transistor with portions of the field effect transistor that are not covered by the gate feature. Metal suicides are not formed where the metal layer is not contacted with silicon containing layers/components of the field effect transistor.

Although not shown in FIG. 12, a metal layer is formed over the field effect transistor. The metal layer can contain any suitable metal compound that can be converted to metal silicides in a subsequent process. Examples of metals include refractory metals, such as tungsten, tantalum, molybdenum and the like; and metals of Group VIII of the Periodic Table, such as platinum, palladium, cobalt, nickel, and the like. The metal layer can be converted to form, in a subsequent heat treatment, a metal silicide compound with underlying silicon in the silicon substrate and/or in the gate electrode. The metal layer can be formed by any suitable technique, for example, CVD, physical vapor deposition (PVD), and the like. The metal layer can have any suitable thickness that depends on, for example, a desired thickness of the metal silicide formed in the subsequent process.

The metal layer can be converted to the metal suicides by heating the metal layer to cause a chemical reaction between the metal layer and the underlying silicon containing layer/component of the field effect transistor. In one embodiment, the metal suicides are formed by chemical reactions of the metal layer with the silicon of the underlying silicon substrate and/or with the polysilicon of the gate electrodes. During the silicidation process, the metal of the metal layer can diffuse into the underlying silicon containing layer/component and form the metal silicides. As a result, the metal suicides can be selectively formed on the field effect transistor.

The metal silicides can have any suitable height that depends on, for example, the desired implementations and/or the field effect transistor being fabricated. In one embodiment, the metal silicides have a height of about 5 nm or more and about 30 nm or less. In another embodiment, the metal silicides have a height of about 10 nm or more and about 25 nm or less.

Choice of suitable conditions and parameters (e.g., temperature, duration of heat treatment, and the like) of the silicidation process depends on, for example, the desirable dimensions (e.g., height) of the metal silicides, the configuration and/or constituent of the metal layer and/or the underlying silicon containing component/layer, the desired implementations and/or the field effect transistor being fabricated, and the like. For example, the metal silicides are formed by rapid thermal annealing (RTA).

Portions of the metal layer, for example, over the side spacer and the STIs remain unreacted and can be removed by, for example, etching. The unreacted portions of the metal layer can be removed by contacting the unreacted metal portions with any suitable metal etchant that does not substantially affect or damage the integrity of other layers/components of the field effect transistor such as the metal silicides. Examples of metal etchants include an oxidizing etchant solution. Examples of oxidizing etchants include an acidic solution containing, for example, H2SO4/H2O2, HNO3/H2O2, HCl/H2O2, H2O2/NH4OH/H2O, H3PO4, HNO3, CH3COOH, and the like. Other metal etchants can also be used as long as they are capable of removing the unreacted portions of the metal layer selective to other components/layers of the field effect transistor.

The metal silicides can have a significantly lower sheet resistance than silicon and polysilicon. The metal suicides formed on the polysilicon containing gate is generally referred to as a polycide gate, which significantly reduces the resistance of the gate structure, as compared to a polysilicon gate. As a result, the overall conductivity of the gate electrode may be increased.

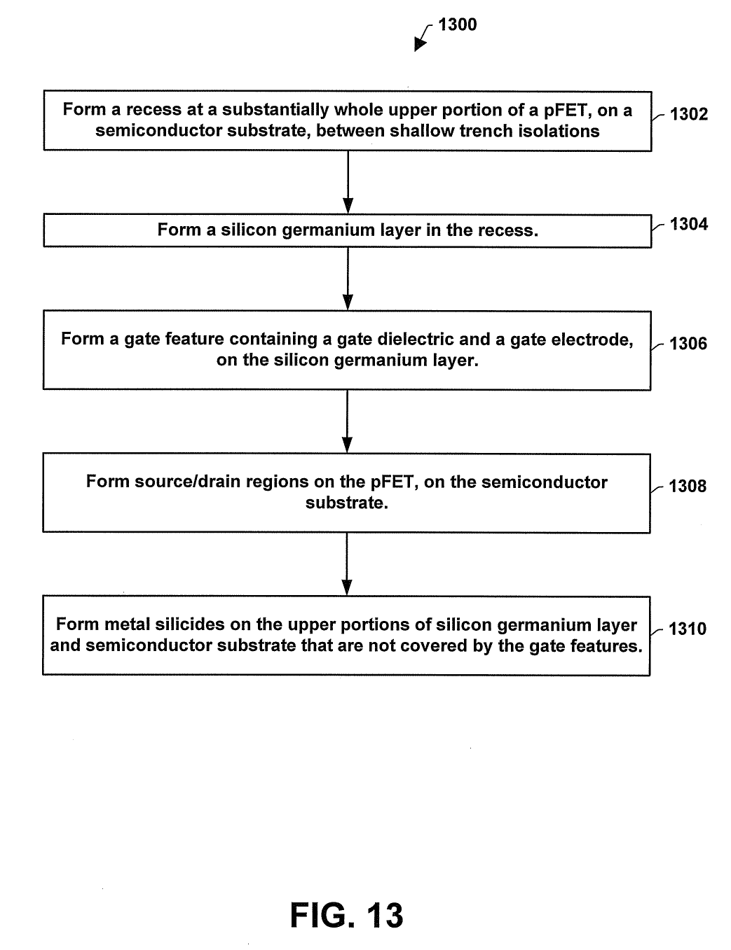

FIG. 13 illustrates an exemplary methodology 1300 of forming a semiconductor device. At 1302, a recess is formed at a substantially whole upper portion of a p-FET, on a semiconductor substrate, between shallow trench isolations. As discussed previously, an n-FET can also be on the semiconductor substrate, where the semiconductor substrate comprises a CMOS device. In an embodiment, the recess can have a (100) plane of a bottom surface and a (111) plane of side surfaces. In an additional embodiment, the semiconductor substrate is heated to change the (111) plane of the side surfaces of the recess to two or more different planes. At 1304, a silicon germanium layer is formed in the recess. In an embodiment, the silicon germanium layer has a (100) plane of a bottom surface and a top surface and two or more planes of side surfaces.

At 1306, a gate feature containing a gate dielectric and a gate electrode is formed on the silicon germanium layer. The gate dielectric having a high-k dielectric. For instance, the high-k dielectric can comprise a variety of Hafnium (Hf) Compounds in combination with a Rare Earth (RE) Compound. In a non-limiting example, the high-k dielectric can comprise Hf oxide and Lanthanum (HfO2+La). In further non-limiting examples, the Hf Compounds can include Zr oxide, HfZr oxide, Hf silicate, Zr silicate, or HfZr silicate, and the RE Compound can include a RE metal (REM) and/or RE oxide (REO), such as Y, Dy, Sr, Ba, Yb, Lu, Mg, Be, Sc, Ce, Pr, Nd, Eu, Gd, Tb, or Er. It should be appreciated, however, that the preceding list is provided merely by way of example and that other compositions could also be utilized.

In addition, specific non-limiting examples of compositions that can be utilized for the gate electrode 118 include metals such as Ti, Hf, Ta, W, Al, Ru, Pt, Re, Cu, Ni, Pd, Ir, and/or Mo; nitrides and carbides such as TiN, TaN, TiC, TaC, WN, WC, and/or HfN; conductive oxides such as RuOx and/or ReOx; metal-metal-alloys such as Ti—Al, Hf—Al, Ta—Al, and/or TaAlN; multi-stacked structures of the preceding compositions, such as TiN/W, TiN/Ti—Al, Ta/TiN/Ti—Al, or the like. It should be appreciated, however, that the preceding list is provided by way of example and that other compositions could be utilized for the gate electrode.

At 1308, source/drain regions are formed in the semiconductor substrate. In an embodiment, source/drain extension regions and source/drain pockets can also be formed in the semiconductor substrate. At 1310, metal suicides are formed on the upper portions of silicon germanium layer and semiconductor substrate that are not covered by the gate feature.

Although not shown in FIG. 13, the recess can be formed by an anisotropic chemical wet etching. In another embodiment, the trench is formed by using a tetramethylammonium hydroxide solution or an ammonium hydroxide solution. In yet another embodiment, the silicon germanium is formed by a silicon germanium epitaxial process. In still yet another embodiment, the (111) plane of the side surfaces of the recess is changed to two or more different planes by heating the semiconductor substrate in hydrogen at a temperature of about 700 degrees Celsius or more and about 1,300 degrees Celsius or less for about 5 minutes or more and about 100 minutes or less.

Although not shown in FIG. 13, contact holes, conductive lines, and other suitable components can be formed by any suitable semiconductor device fabrication processes. General examples of semiconductor device fabrication processes include masking, patterning, etching, cleaning, planarization, thermal oxidation, implantation, annealing, thermal treatment, and deposition techniques normally used for making semiconductor devices.

Although not shown in FIG. 13, a gate feature similar to the gate feature in 1306 can be formed on the n-FET on the semiconductor substrate. The gate feature formed on the n-FET can have the same high-k dielectric constant and the same gate electrode material as the gate feature formed on the p-FET. In addition, similar to 1308, source/drain regions can be formed on the n-FET, and similar to 1310, metal silicides can be formed on the upper portions of the n-FET that are not covered by the gate feature. As discussed supra, it is to be appreciated that the implementation of the silicon germanium layer in the p-FET trench can enable the use of a single high-K dielectric and metal gate for both the p-FET and n-FET to obtain a suitable threshold voltage.

What has been described above includes examples of the disclosed innovation. It is, of course, not possible to describe every conceivable combination of components or methodologies for purposes of describing the disclosed innovation, but one of ordinary skill in the art can recognize that many further combinations and permutations of the disclosed innovation are possible. Accordingly, the disclosed innovation is intended to embrace all such alterations, modifications and variations that fall within the spirit and scope of the appended claims. Furthermore, to the extent that the term “contain,” “includes,” “has,” “involve,” or variants thereof is used in either the detailed description or the claims, such term can be inclusive in a manner similar to the term “comprising” as “comprising” is interpreted when employed as a transitional word in a claim.

With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

Further, while certain embodiments have been described above, it is to be appreciated that these embodiments have been presented by way of example only, and are not intended to limit the scope of the claimed subject matter. Indeed, the novel methods and devices described herein may be made without departing from the spirit of the above description. The accompanying claims and their equivalents are intended to cover such forms or modifications as would fall within the scope and spirit of the subject innovation.

In addition, it should be appreciated that while the respective methodologies provided above are shown and described as a series of acts for purposes of simplicity, such methodologies are not limited by the order of acts, as some acts can, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

What is claimed is:

1. A semiconductor device, comprising:
a substrate;
a p-type field effect transistor, on the substrate, the p-type field effect transistor comprising:
a silicon germanium layer formed on the substrate;
a first gate dielectric layer formed on the silicon germanium layer, the first gate dielectric having a high-k dielectric material, the high-k dielectric material including a hafnium compound and a rare earth compound; and
a first gate electrode formed on the first gate dielectric layer having a second material;
a n-type field effect transistor, on the substrate, the n-type field effect transistor comprising:
a second dielectric layer formed on the substrate, the second dielectric layer having the high-k dielectric material; and
a second gate electrode formed on the second gate dielectric having the second material.

2. The semiconductor device according to claim 1, wherein the hafnium compound in the first material includes at least one of: Hf oxide, Zr oxide, HfZr oxide, Hf silicate, Zr silicate, or HfZr silicate.

3. The semiconductor device according to claim 1, wherein the rare earth compound is La.

4. The semiconductor device according to claim 1, wherein the rare earth compound includes at least one of: Y, Dy, Sr, Ba, Yb, Lu, or Mg.

5. The semiconductor device according to claim 1, wherein the rare earth compound includes at least one of: Be, Sc, Ce, Pr, Nd, Eu, Gd, Tb, or Er.

6. The semiconductor device according to claim 1, wherein the first gate dielectric layer, having the high-k dielectric material, formed on the silicon germanium layer generates a negative static charge in the p-type field effect transistor.

7. The semiconductor device according to claim 1, wherein the first gate dielectric layer, having the high-k dielectric material, formed on the silicon germanium layer shifts a threshold voltage of the p-type field effect transistor in a positive direction.

8. The semiconductor device according to claim 7, wherein the shift in the threshold voltage is based at least in part on a ratio of silicon to germanium in the silicon germanium layer.

9. The semiconductor device according to claim 1, further comprising a recess formed on the substrate having a height of about 2 nm or more and about 25 nm or less.

10. A semiconductor device, comprising:
a substrate;
a p-type field effect transistor, on the substrate, the p-type field effect transistor comprising:
a silicon germanium layer formed on the substrate;
a gate dielectric formed from a first material on the silicon germanium layer, the first material having a high dielectric constant, and including a hafnium compound and a rare earth compound; and
a gate electrode formed from a second material on the gate dielectric.

11. The semiconductor device according to claim 10, wherein the hafnium compound in the first material includes at least one of: Hf oxide, Zr oxide, HfZr oxide, Hf silicate, Zr silicate, or HfZr silicate.

12. The semiconductor device according to claim 10, wherein the rare earth compound in the first material includes at least one of: La, Y, Dy, Sr, Ba, Yb, Lu, Mg, Be, Sc, Ce, Pr, Nd, Eu, Gd, Tb, or Er.

13. The semiconductor device according to claim 10, wherein the combination of silicon germanium and the first material including a hafnium compound and a rare earth compound produces a negative static charge in the p-type field effect transistor.

14. The semiconductor device according to claim 10, wherein the combination of silicon germanium and the first material including a hafnium compound and a rare earth compound shifts a threshold voltage of the p-type field effect transistor.

15. The semiconductor device according to claim 14, wherein the shift in the threshold voltage is about 500 mV or less in the positive direction.

16. The semiconductor device according to claim 10, wherein the substrate further includes an n-type field effect transistor having a second gate dielectric formed from the first material at the upper most portion of the n-type type field effect transistor, and a second gate electrode formed from the second material disposed on the second gate dielectric.

17. A method of fabricating a semiconductor device, comprising:
forming a recess at a substantially whole upper portion of a p-type field effect transistor region, on a semiconductor substrate, between shallow trench isolations;
forming a silicon germanium layer in the recess;
forming a gate dielectric having a high dielectric constant from a hafnium compound and a rare earth compound on the silicon germanium layer in the p-type field effect transistor region; and
forming a gate electrode on gate dielectric using a first material in the p-type field effect transistor region.

18. The method of claim 17, wherein forming the gate dielectric having a high dielectric constant, k, from the hafnium compound and the rare earth compound includes forming the hafnium compound using at least one of: Hf oxide, Zr oxide, HfZr oxide, Hf silicate, Zr silicate, or HfZr silicate, and forming the rare earth compound using at least one of: La, Y, Dy, Sr, Ba, Yb, Lu, Mg, Be, Sc, Ce, Pr, Nd, Eu, Gd, Tb, or Er.

19. The method of claim 17, further comprising shifting a threshold voltage of the p-type field effect transistor in a positive direction by controlling a concentration of germanium in the silicon germanium layer.

20. The method of claim 17, further comprising:
forming a second gate dielectric in an n-type field effect transistor region, on the semiconductor substrate, using the same hafnium compound and rare earth compound as the first gate dielectric layer; and
forming a second gate electrode on the second gate dielectric using the first material in the n-type field effect transistor region.
